(19) United States
(12) Patent Application Publication
(10) Pub. No.: US 2011/0280092 A1
(43) Pub. Date: Nov. 17, 2011

(54) Multi-Bank Read/Write To Reduce Test-Time In Memories

(75) Inventor: Hari Rao, San Diego, CA (US)

(73) Assignee: QUALCOMM Incorporated, San Diego, CA (US)

(21) Appl. No.: 12/777,687

(22) Filed: May 11, 2010

(51) Int. Cl. G11C 29/00; G11C 7/00; G11C 8/00

(52) U.S. Cl. 365/201; 365/230.03; 365/203

(57) ABSTRACT

Apparatuses and methods for multi-bank read/write architecture to reduce test time in memory devices are disclosed. A memory device can include a memory cell array including a plurality of memory banks. A bank decoding circuit can include logic configured to simultaneously select each of the plurality of memory banks. An Input/Output (IO) circuit can be coupled to the memory cell array and bank decoding circuit. The IO circuit can include failure detection logic configured to detect a failure in any of plurality of memory banks and selected IO simultaneously in one clock cycle.

### FIELD OF DISCLOSURE

The present application relates to memory devices, and more particularly to multi-bank read/write architecture to reduce test time in memory devices.

### BACKGROUND

Random access memory (RAM) is a ubiquitous component of modern digital architectures. RAM can be utilized within stand-alone devices or can be integrated or embedded within devices that use RAM, such as microprocessors, microcontrollers, application specific integrated circuits (ASICs), system-on-chip (SoC), and other like devices. Further, RAM can be volatile or non-volatile. Volatile RAM loses its stored information whenever power is removed. Non-volatile RAM can maintain its memory contents even when power is removed from the memory. Although non-volatile RAM has the ability to maintain its contents even when power is no longer applied, conventional non-volatile RAM has slower read/write times than volatile RAM.

Many types of relatively large, commodity memory devices are currently available including static random access memory (SRAM), dynamic random access memory (DRAM), magnetoresistive random access memory (MRAM), electrically programmable read only memory (EPROM), ferroelectric random access memory (FRAM), flash memory and the like. Regardless of the configuration, the primary purpose of the memory device is to store data. Functionally, data may be written to the memory, read from it and, in the case of DRAM, may be periodically refreshed to maintain the integrity of the stored data. Each cell of a memory array serves to store a value or a charge representative of either a logic level “1” or “0”.

In the design of semiconductor memories, memory cells may be arranged into sub-arrays with row select circuitry on one side of the sub-arrays and data sensing circuitry on the two sides orthogonal to the row select circuitry. The overall memory is, in turn, built up into multiple banks of multiple sub-arrays in a uniform arrangement.

Memory testing operations may be utilized in order to resolve a variety of issues. For example, coupling issues from one word line to another word line, the memory cell may be stuck at a logical “0” or “1”, memory pattern sensitivity where a logical “0” is being written to a specific cell, and the memory device writes a logical “1” in a neighboring cell, etc.

### SUMMARY

Exemplary embodiments are directed to systems and methods for multi-bank read/write architecture to reduce test time in memory devices.

In current memory architectures, a memory cell array is tested on a per bank basis, which tends to be slow, and test-times tend to scale with the number of banks, number of patterns, and number of visits per location (for read/write). Further, since test times and test costs are increasing dramatically, a need exists for a memory architecture that allows for the simultaneous testing of a plurality of memory banks.

Accordingly, an embodiment of the invention can include a memory device comprising: a memory cell array including a plurality of memory banks; a bank decoding circuit including logic configured to simultaneously select each of the plurality of memory banks; and an Input/Output (IO) circuit coupled to the memory cell array and bank decoding circuit, wherein the IO circuit includes failure detection logic configured to detect a failure in any of plurality of memory banks and selected IO simultaneously in one clock cycle.

Another embodiment of the invention can include a method for reducing memory test time, the method comprising: simultaneously writing and reading each of a plurality of memory banks in a memory array; and testing of the plurality of memory banks simultaneously in one cycle of a clock by local matching of read data with previously written data for each bank.

Another embodiment of the invention can include a method for reducing memory test time, the method comprising: step for simultaneously writing and reading each of a plurality of memory banks in a memory array; and step for testing the plurality of memory banks simultaneously in one cycle of a clock by local matching of read data with previously written data for each bank.

Another embodiment of the invention can include an apparatus for reducing memory test time, the method comprising: means for simultaneously writing and reading each of a plurality of memory banks in a memory array; and means for testing the plurality of memory banks simultaneously in one cycle of a clock by local matching of read data with previously written data for each bank.

### BRIEF DESCRIPTION OF THE DRAWINGS

The accompanying drawings are presented to aid in the description of embodiments and are provided solely for illustration of the embodiments and not limitation thereof.

FIG. 1 illustrates a generic memory array that can relate to embodiments disclosed herein.

FIG. 2A illustrates a schematic diagram depicting a conventional bank decoding circuit 200.

FIG. 2B illustrates a diagram of write and read clock cycles employing the conventional memory testing architecture.

FIG. 2C illustrates a diagram of write and read clock cycles employing the memory cell array testing architecture disclosed herein.

FIG. 3 illustrates a block diagram illustrating an exemplary bank decoding device.

FIG. 4 illustrates a schematic diagram of the bank decoding logic.

FIG. 5 illustrates a schematic diagram of the IO logic.

FIG. 6 illustrates a schematic diagram of a column of memory cells and a sense amp latch.

FIG. 7 illustrates a timing diagram for various parameters and signals coupled to different ports of the elements illustrated in FIG. 4 and FIG. 5.

### DETAILED DESCRIPTION

Aspects of the various embodiments are disclosed in the following description and related drawings directed to specific embodiments. Alternate embodiments may be devised without departing from the scope of the invention. Additionally, well-known elements of the embodiments will not be described in detail or will be omitted so as not to obscure the relevant details of the embodiments.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of the various disclosed embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of embodiments disclosed herein may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

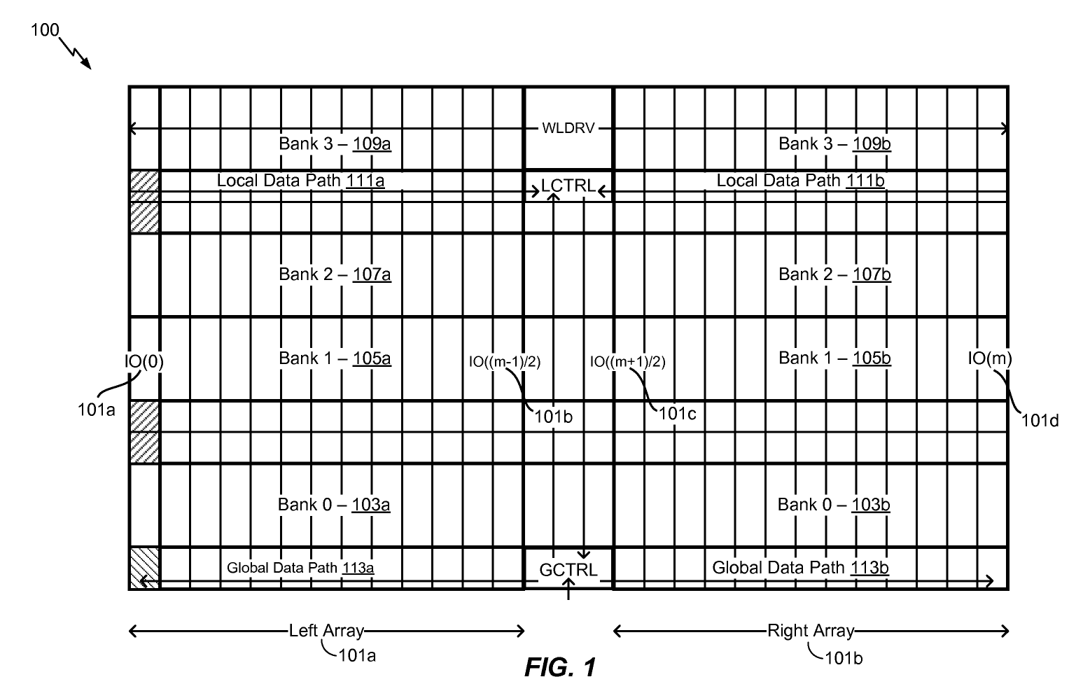

Referring to FIG. 1, a generic memory array according to one embodiment is illustrated. The memory array 100 may be split into two portions, a left array 100a and a right array 100b. Further, the memory array 100 may include a plurality of memory banks In this exemplary embodiment, the memory banks can include Bank 0 103a and 103b, Bank 1 105a and 105b, Bank 2 107a and 107b and Bank 3 109a and 109b. In FIG. 1, only four banks are shown for the memory array. However, it is understood that any number of banks more or less may be utilized for each memory array.

A global control (GCTRL) may be used to generate control signals by processing incoming read/write commands and can also be used to generate pre-decoded lines by processing incoming addresses. The memory array 100 may also include a global data path 113a, 113b which may capture incoming write data and can also drive read data out.

A local control (LCTRL) may be used to further process any control/pre-decoded signals from GCTRL in order to generate bank specific control signals. The memory array 100 may also include a local data path 111a and 111b. The local data path may include sensing circuitry which may read data and write-circuitry which can write data enabled by the control signals from the LCTRL.

Further, each memory bank may include a plurality of Input/Output (IO) sub-blocks. In this exemplary embodiment, the memory array can be divided into “m” IO sub-blocks. For example, IO sub-blocks IO(0) 101a and IO((m−1)/2) 101b are shown on a left portion of memory array 100 and IO sub-blocks IO((m+1)/2) 101c and IO(m) 101d are shown on a right portion of memory array 100.

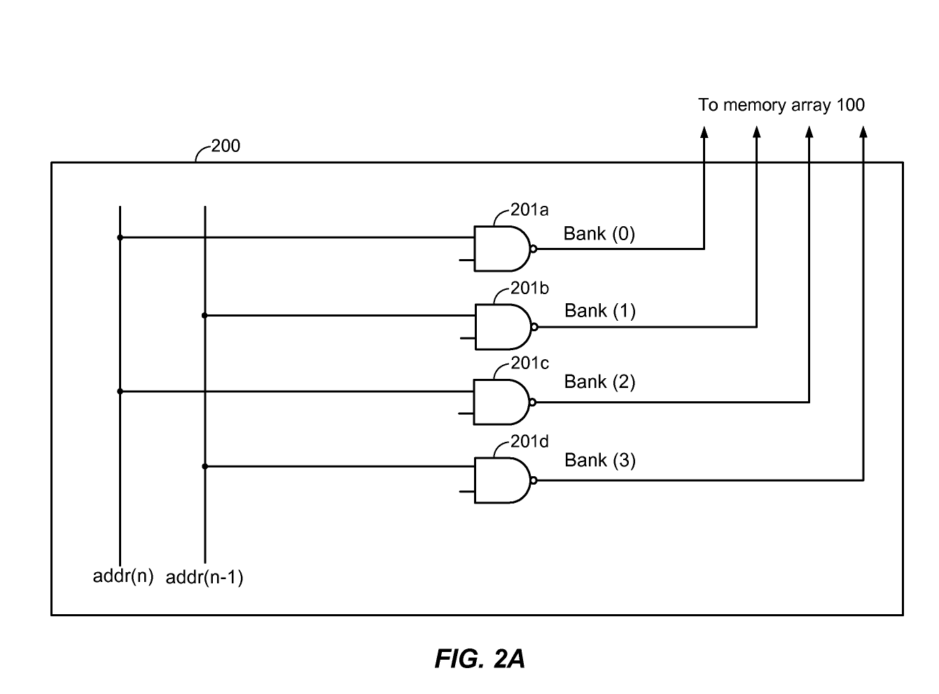

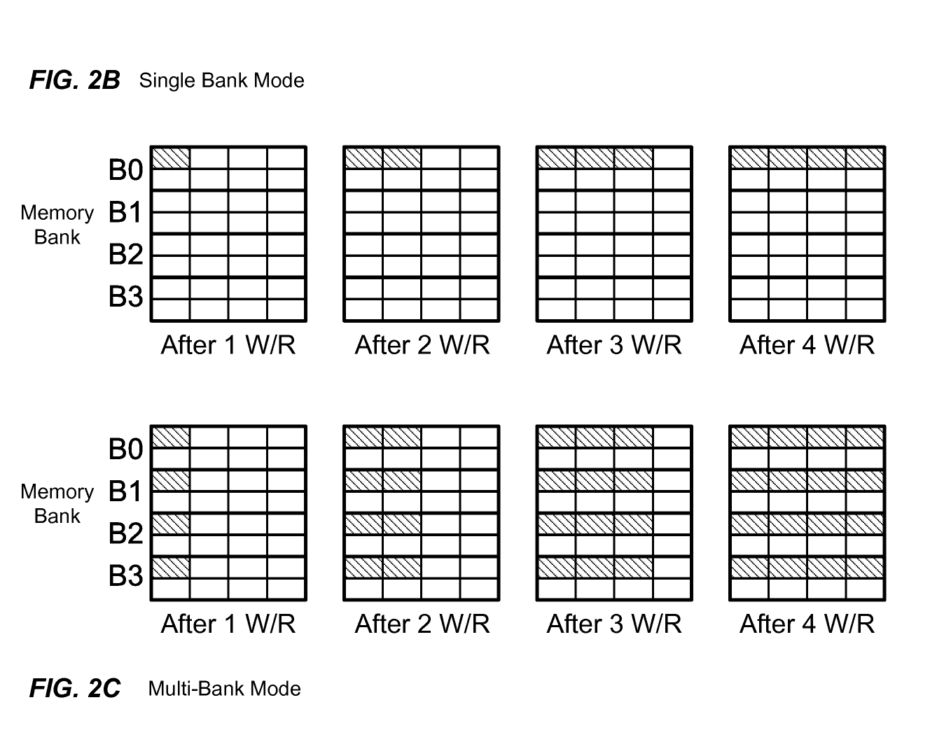

FIG. 2A is a schematic diagram depicting a conventional bank decoding circuit 200. The bank decoding circuit 200 may act as a controlling device of the memory array 100 during memory testing operations. The bank decoding circuit 200 may include NAND gates 201a, 201b, 201c and 201d. Each of the NAND gates 201a, 201b, 201c and 201d can be coupled to address bits addr(n) and addr(n−1) which may control the selection of a single memory bank (during one clock cycle). While testing a memory cell array, one bank of memory can be selected by the bank decoding circuit 200 during one clock cycle. Thus, in order to select or control more than one memory bank utilizing conventional bank decoding circuits several clock cycles must pass.

FIG. 2B illustrates each of the memory banks in memory cell array 100 and the number of read write operations performed for each memory bank in a single bank mode. For example, several clock cycles are required in order to write and read data from a memory bank employing the conventional memory testing architecture (as illustrated by portions filled with diagonal lines). FIG. 2C illustrates some of the advantages of implementing the memory cell array testing architecture disclosed herein. Specifically, FIG. 2C illustrates that a plurality of memory banks can be tested simultaneously in a parallel processing based manner. Further, after several clock cycles (write/read operations) have passed, the number of memory banks tested (shown in FIG. 2C) greatly increases when compared with the conventional memory testing architecture (shown in FIG. 2B).

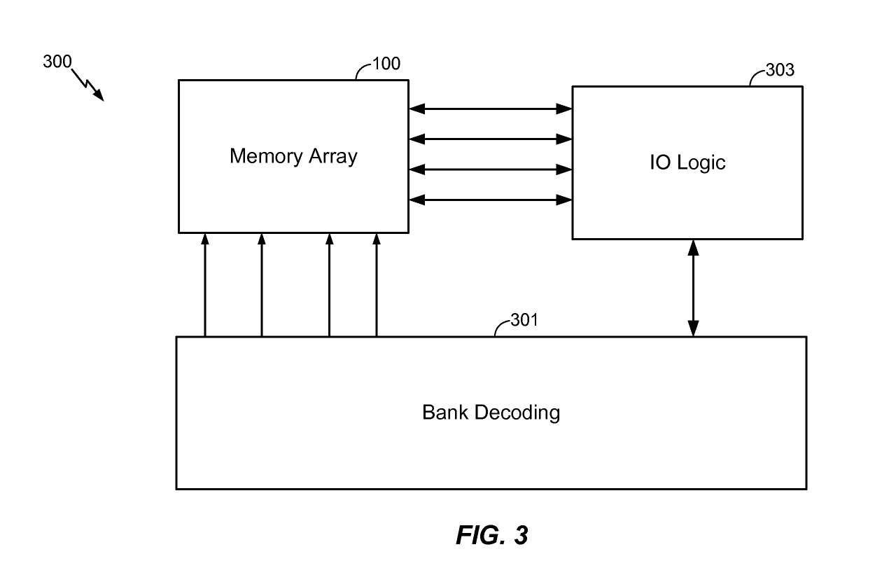

FIG. 3 is a block diagram depicting an exemplary bank decoding device 300. The bank decoding device 300 may include memory array 100, bank decoding logic 301 and IO logic 303. The bank decoding logic 301 can be coupled to memory array 100 and IO logic 303. The bank decoding logic 301 may control the selection of memory banks located within the exemplary memory array 100 shown in FIG. 1. The bank decoding logic 301 can be used to perform testing of the memory array 100 by selecting each of the memory banks contained within memory array 100 during one clock cycle. Further, the testing of the memory array 100 may include writing data to each of the memory banks contained within the memory array 100 and then reading data from each of the memory banks to ensure data accuracy. Further, IO Logic 303 may perform data processing to ensure accuracy.

The exemplary circuitry described in FIGS. 3-5 can be utilized to determine how many IO sub-blocks failed during testing, which specific IO sub-blocks failed during testing and which memory banks within the memory cell array the failed IO sub-block belonged to.

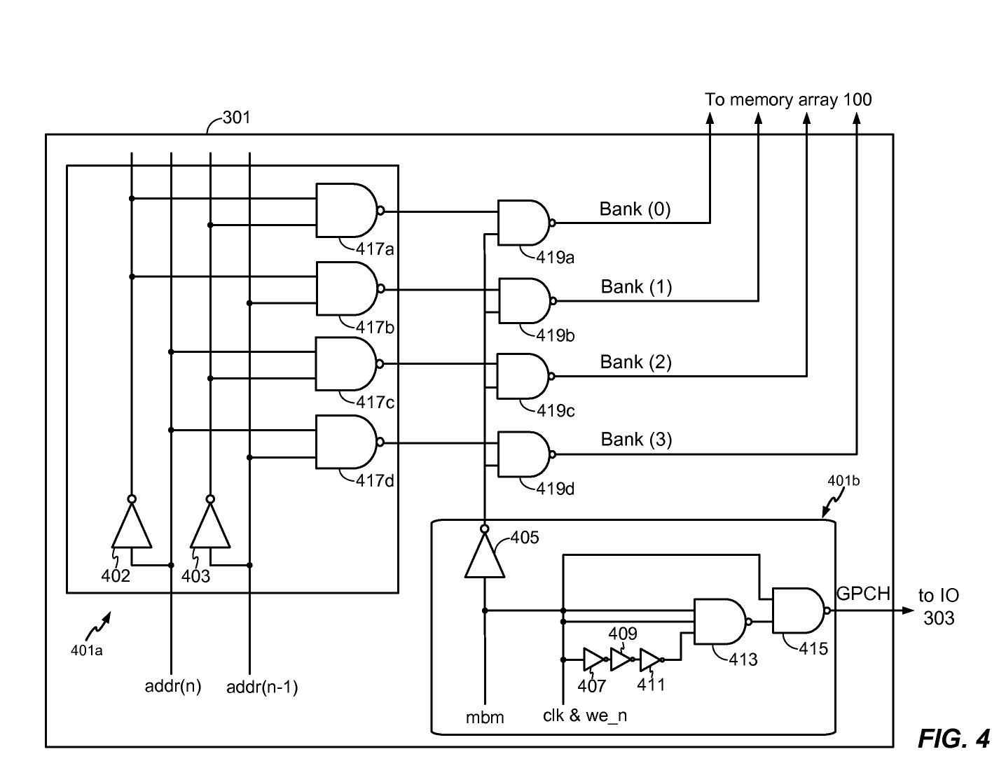

FIG. 4 is a schematic diagram of the bank decoding logic 301. The bank decoding logic 301 is coupled to the memory array 100 and can directly control the memory array 100. The bank decoding logic 301 can select specific memory banks within the memory array 100 by outputting a control signal (e.g., a logical “1”). Thus, a logical “1” outputted by the bank decoding logic 301 results in the selection of any memory banks coupled to the decoding logic 301.

The bank decoding logic 301 may include two portions (left portion 401a and right portion 401b) that enable the selection of multiple memory banks in one clock cycle. The two portions of the bank decoding logic 301 are the left portion 401a of the bank decoding logic 301 driven by address bits addr(n) and addr(n−1) and the right portion 401b of the bank decoding logic 301 driven by the multibank control (mbm) control signal.

As described above, the left portion 401a of the bank decoding logic 301 can be driven by address bits addr(n) and addr(n−1). The bank decoding logic 301 may have n address bits and 2ⁿ memory banks. In this exemplary embodiment, four memory banks are present in the memory cell array 100, thus there are two address bits. The address bits addr(n) and addr(n−1) are coupled to NAND gates 417a, 417b, 417c and 417d. However, inverters 402 and 403 can be positioned between the address bits addr(n) and addr(n−1) and the NAND gates. For example, inverter 402 is positioned between address bit addr(n) and NAND gates 417a and 417b. Further, inverter 403 is positioned between address bit addr(n−1) and NAND gates 417a and 417c. The address bits addr(n) and addr(n−1), inverters 402 and 403 and NAND gates 417a, 417b, 417 c and 417d are utilized as the left portion 401a of the bank decoding logic 301.

As described above, the right portion 401b of the bank decoding logic 301 can be driven by control signal mbm. The control signal mbm is coupled to inverter 405. Inverter 405 is coupled to a plurality of NAND gates. In this exemplary embodiment, inverter 405 is coupled to NAND gates 419a, 419b, 419c and 419d. The other input of the NAND gates 419a, 419b, 419c and 419d are coupled to the output of NAND gates 417a, 417b, 417c and 417d from the left portion 401a of the bank decoding logic 301. The output of each NAND gate 419a, 419b, 419c and 419d is coupled to memory array 100. If the control signal mbm is a logical “1,” then the inverter 405 outputs a logical “0” to the input of NAND gates 419a, 419b, 419c and 419d. Thus, each of the NAND gates 419a, 419b, 419c and 419d has at least one input of a logical “0.” As a result of the functionality of the NAND gates 419a, 419b, 419c and 419d, when one of the inputs is a logical “0” then the corresponding output is a logical “1” regardless of the value of the other input. Further, when one of the outputs of the NAND gates 419a, 419b, 419c and 419d is a logical “1”, then the corresponding memory bank coupled to the particular NAND gate is selected. As a result, a plurality of memory banks may be selected during one clock cycle.

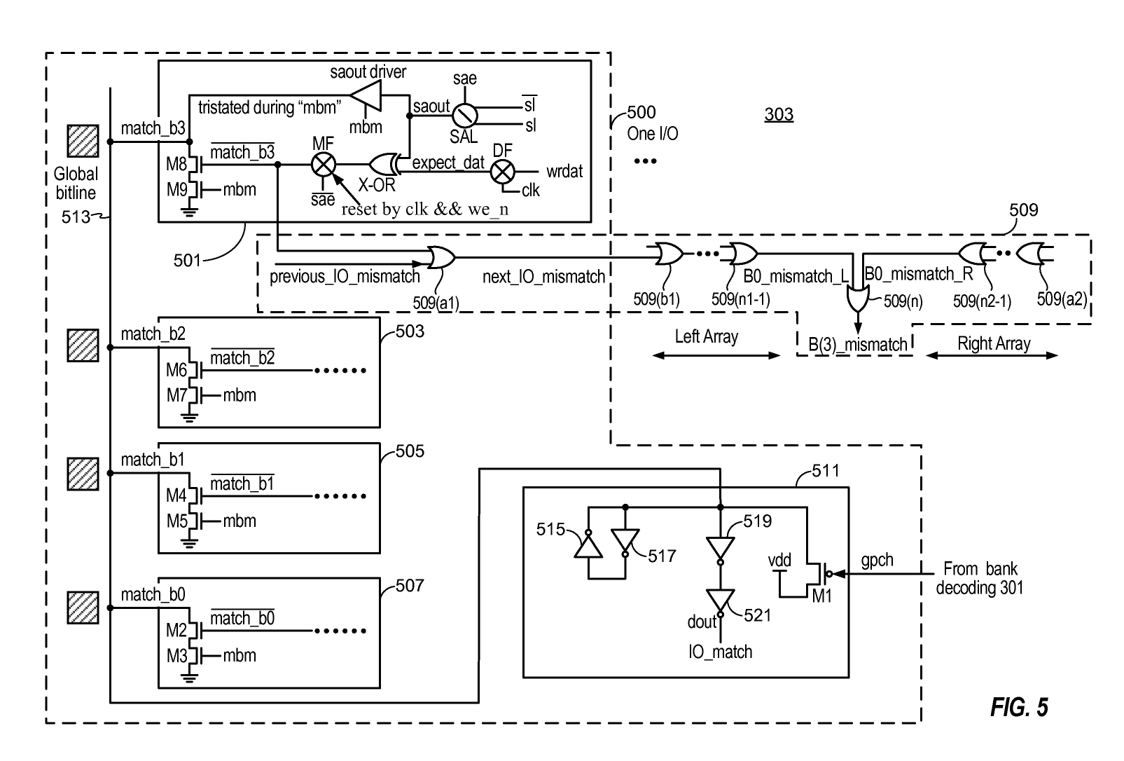

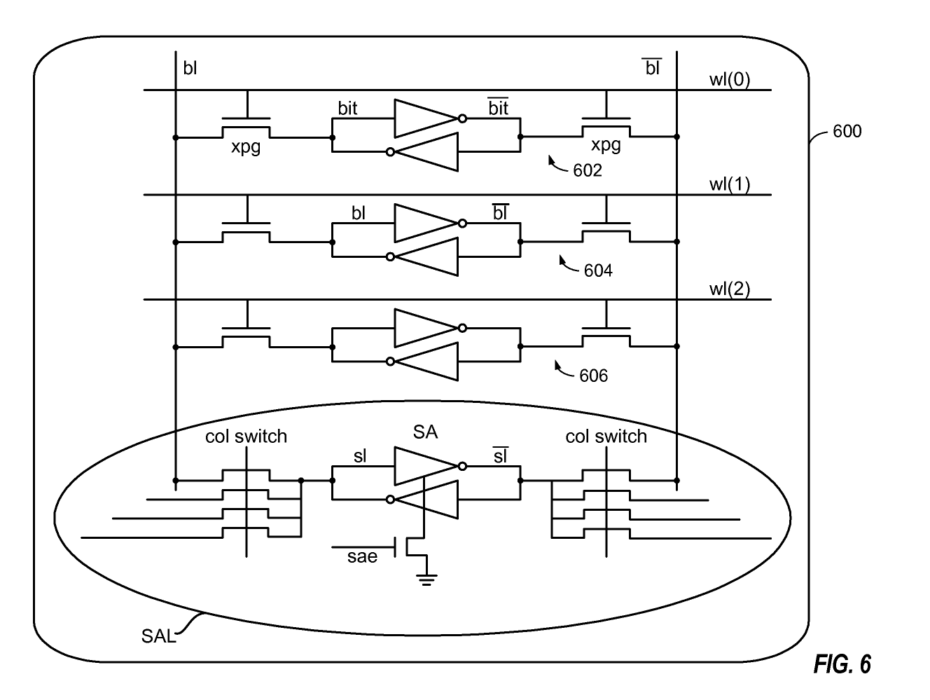

FIG. 4 also illustrates that control signal mbm can also be coupled to NAND gates 413 and 415. For example, in this particular embodiment NAND gate 413 may have three inputs. Specifically, NAND gate 413 can be coupled to control signal mbm and clock signal clk and signal write enable (we_n). Further, clock signal clk and signal we_n can also be coupled to inverters 407, 409 and 411 which is also coupled to the third input of NAND gate 413. The output of NAND gate 413 can be coupled to one of the inputs of NAND gate 415. The other input of NAND gate 415 can be coupled to control signal mbm. NAND gate 415 can output Global Precharge (gpch) control signal. Control signal gpch can be coupled to IO logic 303. The bank decoding logic 301 illustrated in FIG. 4 can be used to generate a pulse (gpch) during the initial part of the read cycle to precondition the global bit line (513) as a logical high for processing the IO match results from the multiple banks shown in FIG. 5.

FIG. 5 is a schematic diagram of the IO logic 303 (which can be coupled to global precharge (gpch) control 401b described in FIG. 4). IO logic 303 can include a plurality of IO mismatch detection logic 500 and bank mismatch detection logic 509. Details are provided for IO mismatch detection logic 500 for one IO for each bank. However, it will be appreciated that each of the elements can be repeated for both the left and right side IOs. Additionally, details are provided for bank mismatch detection logic 509, which can be repeated for each of the plurality of memory banks.

IO mismatch detection logic 500 can include multiple IO sub-blocks. For example, the mismatch detection logic 500 can be made up of a plurality of IO sub-blocks (IO sub-block 501, IO sub-block 503, IO sub-block 505 and IO sub-block 507 shown in FIG. 5), where each individual IO sub-block can be utilized to generate a control signal match_b# which is utilized to determine if an error occurred during testing of the memory cell array 100. Further, each individual IO sub-block can be coupled together via a global bit line 513 to IO match output block 511. IO match output block 511 can be coupled to bank decoding logic 301.

As described earlier in FIG. 1, the memory cell array 100 can include IO sub-blocks 101a, 101b, 101c and 101d. Furthermore, during testing of the memory cell array 100, the IO sub-blocks 101a, 101b, 101c and 101d can be utilized to write and read data to the memory cell array 100. IO logic 303 may be utilized to determine how many individual IO sub-blocks failed during testing and which particular IO sub-blocks. IO logic 303 may also be utilized for generating control signal IO_match which can be used to determine if a mismatch occurred in any of the individual IO sub-blocks during a write/read operation (via control signal match_b#). If a mismatch occurred in any of the individual IO sub-blocks during a write/read operation, then an error occurred in the corresponding IO sub-blocks during testing of the memory cell array. Thus, one or many of the memory banks coupled to the particular IO sub-block failed during testing as well.

During testing operations of the memory cell array 100, each individual IO sub-block may write data to a particular memory bank within the memory cell array 100 within one clock cycle. Afterwards, each IO sub-block may read the data (within the same clock cycle as the write operation) from the same memory bank within the memory cell array 100 in order to determine if the memory cell array is properly functioning. If the write and read operations match each other, then the memory cell array 100 is properly functioning. However, if the write and read operations do not match each other, then the memory cell array 100 is not functioning properly.

For example, after IO sub-block 501 performs a write operation to a specific portion of memory cell array 100, IO sub-block 501 can also perform a read operation from the same portion of memory cell array 100. Further, it is understood that each of the components contained within IO sub-block 501 can also be contained within each of the individual IO sub-blocks (e.g. IO sub-blocks 503, 505 and 507).

IO sub-block 501 can include a sense amp latch SAL with inputs SL and SL that can be generated from the memory cell array 100. The sense amp latch SAL can store data read from the memory cell array 100 during the read cycle when the control signal sense amp enable (SAE) is activated. The output of the sense amp latch SAL (saout) is coupled to one input of an Exclusive OR gate X-OR.

IO sub-block 501 can also include a flip-flop DF that can be positioned in parallel with the sense amp latch SAL. The flip-flop DF can hold data that was written to the memory cell array 100 in a previous cycle (wrdat). The flip-flop DF can be triggered by clock signal clk. The output of the flip-flop DF (expect_dat) is coupled to one input of the Exclusive OR gate X-OR.

IO sub-block 501 can also include Exclusive OR gate X-OR that can be coupled to sense amp latch SAL and flip-flop DF. The Exclusive OR gate X-OR can perform a local comparison of the data contained on the input ports (saout & expect_dat). Therefore, in the read cycle, data that is read (saout) is compared with the data that was written (expect_dat) using the Exclusive OR gate X-OR and the match/mismatch result can be stored in flip-flop MF after the SAE control signal is de-activated (described further below). Thus, when the output of the EXCLUSIVE-OR gate X-OR is a logical “1”, then there is a mismatch and when the output of the EXCLUSIVE-OR gate X-OR is a logical “0”, then there is a match. The output of the EXCLUSIVE-OR gate X-OR can be coupled to the match flip-flop MF. Further, the teachings described herein (i.e. the EXCLUSIVE-OR gate X-OR are performed internal to the memory cell array architecture. In conventional systems, the testing performed would be positioned external to the memory cell array architecture.

IO sub-block 501 can also include match flop MF that can be coupled to Exclusive OR gate X-OR. The match flop MF can capture the comparative signal (output by the EXCLUSIVE-OR gate X-OR) since it is a flip-flop device. The match flop MF is triggered by the complement of control signal SAE. If the data that was written to the memory cell array 100 is the same as that which is read, then there is a match and the match flop MF can output a logical “0.” If the output of the match flop is a logical “1,” then there is a mismatch and the data that was read to memory cell array 100 is not the same as that which was read. The output of the match flop MF is m̅a̅t̅c̅h̅_̅b̅3̅ as illustrated in FIG. 5 and is coupled to the stacked transistors M8 and M9. Further, the output of the match flop is also input to Mismatch Block 409.

IO sub-block 501 can also include a two stacked transistors M8 and M9 that can be coupled to the match flop MF. The two stacked transistors M8 and M9 includes a lower portion (M9) and an upper portion (M8). The lower transistor (M9) can be coupled to the test mode (“mbm” or control line) which can enable the lower portion of the stack, and the upper transistor (M8) can be coupled to the output of the match flop MF. The output of the two stacked transistors M8 and M9 is coupled to the global bit line 513.

The global bit line 513 can couple each individual IO sub-block (501, 503, 505 and 507) together and also couples the IO sub-blocks to IO match output block 511. For example, if each of the values coupled to the global bit line 513 is a logical “0” and the global bit line 513 is pre-charged, then there is a match for each of the IO sub-blocks coupled to the global bit line 513. However, if any of the values coupled to the global bit line 513 is a logical “1”, then there is a mismatch for at least one of the IO sub-blocks and the global bit line 513 is discharged. As a result, if the global bit line 513 is discharged, then a mismatch occurred for any number of memory banks. Thus, column information is gathered such that specific columns that are mismatched are now known. However, the specific memory banks belonging to each column are not yet known. Mismatch block 509 may determine the specific memory bank that each mismatched column is associated with. For example, mismatch block 509 can determine if the mismatched column is associated with memory bank 1, bank 2 bank 3 or bank 4.

The global bit line 513 can be coupled to IO match output block 511. Further, it is noted that each time the IO logic 303 can enter the read cycle, the global bit line 513 can be pre-charged in order to set the global bit line 513 to a reference high or a logical “1”. Further, this may be accomplished by utilizing a small pulse. As a result, at the beginning of each read cycle, a small pulse can be utilized which will pull the global bit line 513 to a reference high or a logical “1”. However, if any failures are detected by the IO logic 303, then the global bit line 513 can be pulled to a reference low “0”.

IO match output block 511 can be used to prevent the global bit line 513 from floating. NAND gates 515 and 517 are coupled to each other in a full keeper arrangement such that the output of NAND gate 517 is the input of NAND gate 515 and vice versa. The full keeper arrangement of NAND gates 515 and 517 are coupled to PMOS transistor M1. The full keeper arrangement of NAND gates 515 and 517 can prevent the global bit line 513 from floating since it is coupled to PMOS transistor M1. The full keeper arrangement of inverters 515 and 517 may store the value of the global bit line 513 because it is operating like a latch, regardless of whether the global bit line is pulled low or pulled high. The full keeper arrangement of inverters 515 and 517 are also coupled to inverters 519 and 521. Inverters 519 and 521 are coupled in series such that the output of inverter 519 is the input of inverter 521. The output of inverter 521 is the output signal IO_match. Thus, the IO match output block 511 can hold the IO mismatch data (IO_match) that can be read to determine a pass/fail (e.g., by an external memory tester). Further, the gate portion of PMOS transistor M1 can be coupled to bank decoding logic 301 (via gpch, as discussed in relation to FIG. 4).

Mismatch block 509 may determine the specific memory banks that each mismatched column is associated with. For example, mismatch block 509 can determine if the mismatched column is associated with any of memory bank 0, bank 1, bank 2 or bank 3 for four memory banks. The input of mismatch block 509 is the output of the match flop MF. Mismatch block 509 can be utilized in order to determine if an error occurred for each memory bank. Thus, each of the IO sub-blocks 501, 503, 505 and 507 can have a mismatch block 509 in order to determine if an error occurred for each memory bank. In other words, the mismatch block 509 can determine whether a mismatch occurred or not on a per bank basis.

Mismatch block 509 may include a plurality of OR gates. For example, in FIG. 5, mismatch block 509 can include OR gates 509(a1), 509(b1) and 509(n1−1) for the left portion of memory cell array 100 and OR gates 509(a2), 509(b2) and 509(n2−1) for the right portion of memory cell array 100. Further, if there is a mismatch for any of the IO sub-blocks 501, 503, 505 and 507, then the output of that specific OR gate will be a logical “1” and the output of the Final OR gate 509(n) will also be a logical “1.” Thus, for each mismatched IO sub-block, a specific memory bank can be identified in one clock cycle.

As a result, a bank mismatch and an IO mismatch can be identified in one clock cycle to detect errors that occur in memory cell testing. Thus, multiple clock cycles are not required in order test memory cells with the systems and methods disclosed herein. As a result, the need to test a single memory cell/bank is not required. Thus, a local comparison and global processing are performed across the memory banks and the IO sub-blocks. Further, the clock frequency during test (typically 20 MHz) is a fairly low frequency, therefore the logical operations performed herein can fit into one clock cycle.

FIG. 6 is a schematic diagram of column of memory cells 600 including sense amp latch SAL. FIG. 6 illustrates that the column selection (bit lines) and the row selection (word lines) within memory cell array 100. Data is stored in bit cells (e.g., 602, 604, 606). Further, column switches (col switch) can be used to select specific columns (e.g., 600) within the memory cell array 100. Data can be read and or written using bit lines bl and b̅l̅ (which is the complement of bit line bl) by activating a specific column selection and a specific row selection by a given word line (wl(x)). During reads, the differential voltage on bit line bl and bit line complement b̅l̅ can be sensed and latched by the sense amp (SA), as is known in the art. Accordingly, further details of the operation of the conventional read/write operations are not detailed herein.

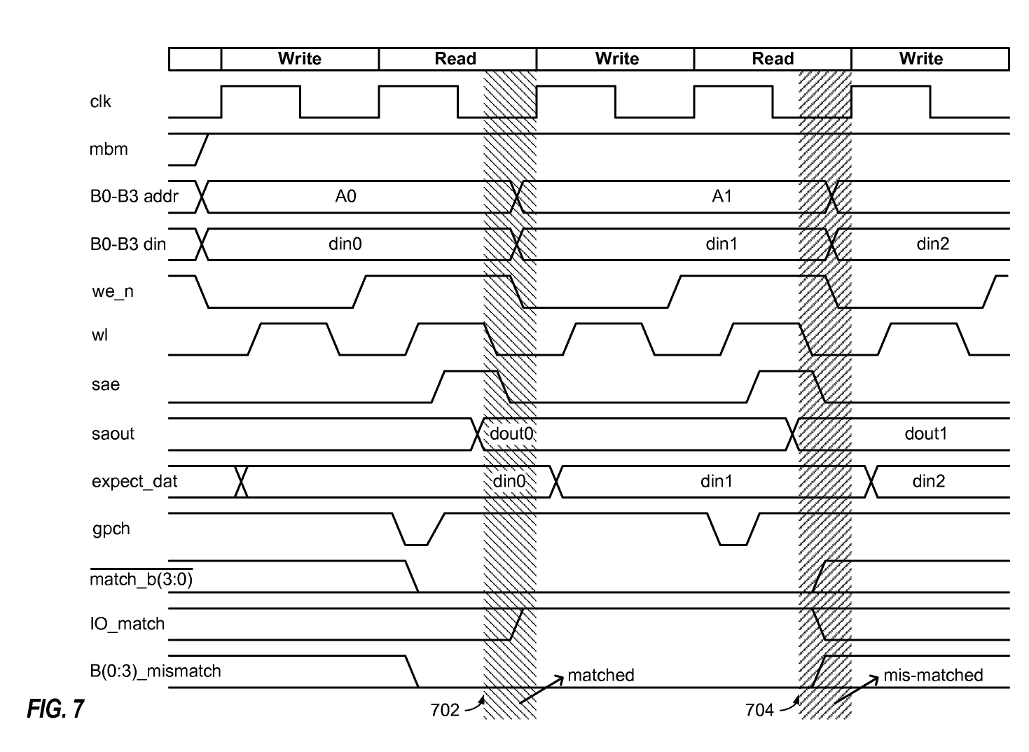

FIG. 7 is a timing diagram for various parameters and signals coupled to different ports of the elements illustrated in FIGS. 4 and 5. For example, global clock signal clk is the primary clock signal for each of the elements within FIGS. 4 and 5 triggered by a clock signal. Global clock signal clk transitions from logical “high” to “low” one time for the write operation and one time for the read operation. Thus, the global clock signal clk transitions from logical “high” to “low” two times per cycle. Further, a cycle is considered as the time for a write and a read operation to occur.

Control signal mbm is the external test signal to select multi-bank mode where each of the memory banks are selected in parallel in order to test them. Thus, when control signal mbm is a logical “1”, then each of the banks is selected for testing in parallel.

B0-B3 addr is that address signal for each of the banks B0-B3 din is the data signal that is held through both the write and read cycle, which allows for a comparison during the read cycle. Write enable (we_n) is an active low which indicates that the write cycle is active when we_n is low, as can be seen from FIG. 7. The word line signal (wl, e.g., wl(0)) is active during both the read and write cycles to select a given row, as discussed in the foregoing.

Sense amp enable (sae) is active during the read cycle and goes high after a delay from the start of the read cycle to latch the data read. The sense amp output (saout) changes after the sense amp is enabled. At this point saout can be compared to the expected data (expect_dat) which is the prior written data (din0).

As discussed in the foregoing, the global precharge (gpch) signal is a pulse signal used to precharge the global bit line (e.g., 513) to a high state so that a known state is established prior to the comparison of the sense amp output and expected data. As discussed above, when there is a mismatch, the global bit line is pulled down to a low logic level and when the signals match, the global bit line remains high. This is illustrated in FIG. 7, in portion 702 where the sense amp output and the expected data match and in portion 704 where there is a mismatch of the sense amp output and expected data.

Signal match_b(3:0) is output by the two stacked transistors M2-M3, M4-M5, M6-M7 and M8-M9, respectively and is controlled by m̅a̅t̅c̅h̅_̅b̅(̅3̅:̅ 0̅)̅, respectively, when the multi-bank mode is active (mbm is high). As discussed above, m̅a̅t̅c̅h̅_̅b̅(̅3̅:̅ 0̅)̅ can determine if a match or a mismatch has occurred for IO sub-blocks 501, 503, 505 and 507. If each of m̅a̅t̅c̅h̅_̅b̅(̅3̅:̅ 0̅)̅ transitions from a logical high to a logical low (see, portion 702), then the signal is matched and there is no error in reading the memory cell array 100. However, if any of m̅a̅t̅c̅h̅_̅b̅(̅3̅:̅ 0̅)̅ transitions from a logical low to a logical high (see, portion 704), then the signal is mismatched and there is an error in reading the memory cell array. This transition of any of the sense amp output and the expected data a high state, will cause the corresponding output match_b(3:0) and the global bit line 513 to be pulled down, which will change output IO_match.

Output signal IO_match is based on the state of global bit line 513. As discussed above, the global bit line 513 can be used to determine if a mismatch has occurred on at least one of IO sub-blocks 501, 503, 505 and 507. If the output signal IO_match is high or transitions to high during the comparison of the sense amp output and the expected data (e.g., 702), then the data is matched for each bank and there is no error in reading the memory cell array 100. However, if the output signal IO_match transitions from a logic high to a logic low, then the comparison of the sense amp output and the expected data on at least one of memory banks (3:0) is mismatched and there is an error in reading the memory cell array 100.

Signal B(0:3)_mismatch can be used to determine which bank or banks have a mismatch. As discussed above, the signal B(0:3)_mismatch can determine if a mismatch as occurred in a given bank by cascaded OR operations of m̅a̅t̅c̅h̅_̅b̅(̅3̅:̅ 0̅)̅ for respective IO (see, e.g., 509). If the signal B(0:3)_mismatch transitions from a logical low to a logical high (see, portion 704), then the signal is mismatched for the respective bank (0:3) and there is an error in reading the memory cell array 100. However, if the signal B(0:3)_mismatch transitions from a logical high to a logical low or maintains a low state (see, portion 702) during the comparison, then the signal is matched and there is no error in reading the memory cell array for the respective bank.

It will be appreciated that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, it will be appreciated that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

It will be appreciated that memory arrays including the test circuitry, as illustrated for example in FIGS. 1, 3, 4 and 5, may be included within a mobile phone, portable computer, hand-held personal communication system (PCS) unit, portable data units such as personal data assistants (PDAs), GPS enabled devices, navigation devices, set top boxes, music players, video players, entertainment units, fixed location data units such as meter reading equipment, or any other device that stores or retrieves data or computer instructions, or any combination thereof. Accordingly, embodiments of the disclosure may be suitably employed in any device which includes memory arrays as disclosed herein.

The foregoing disclosed devices and methods may be designed and configured into GDSII and GERBER computer files, stored on a computer-readable media. These files are in turn provided to fabrication handlers who fabricate devices based on these files. The resulting products are semiconductor wafers that are then cut into semiconductor die and packaged into a semiconductor chip. The chips are then employed in devices described above.

Accordingly, embodiments can include machine-readable media or computer-readable media embodying instructions which when executed by a processor transform the processor and any other cooperating elements into a machine for performing the functionalities described herein as provided for by the instructions. Accordingly, the scope of the invention is not limited to illustrated examples and any means for performing the functionality described herein are included in embodiments.

While the foregoing disclosure shows illustrative embodiments, it should be noted that various changes and modifications could be made herein without departing from the scope of the invention as defined by the appended claims. For example, it will be appreciated that, while specific logic circuitry may be illustrated to aid in the explanation of the various embodiments, alternative logic circuitry can be used to achieve the same functional results. The functions, steps and/or actions of the method claims in accordance with the embodiments described herein need not be performed in any particular order. Furthermore, although elements of the embodiments may be described or claimed in the singular, the plural is contemplated unless limitation to the singular is explicitly stated.

What is claimed is:

1. A memory device comprising:
a memory cell array including a plurality of memory banks;
a bank decoding circuit including logic configured to simultaneously select each of the plurality of memory banks; and
an Input/Output (IO) circuit coupled to the memory cell array and bank decoding circuit, wherein the IO circuit includes failure detection logic configured to detect a failure in any of plurality of memory banks and selected IO simultaneously in one clock cycle.

2. The memory device of claim 1, wherein the bank decoding circuit further comprises:
logic configured to generate a global precharge signal to precharge a global bit line in the IO circuit.

3. The memory device of claim 2, wherein the global bit line is coupled to a selected IO of each of the plurality of memory banks and wherein the failure detection logic is configured to discharge the global bit line if a mismatch is detected on any of the selected IO.

4. The memory device of claim 1, wherein the failure detection logic comprises:
IO mismatch detection logic; and
bank mismatch detection logic.

5. The memory device of claim 4, wherein the IO mismatch detection logic comprises:
a comparison logic configured to compare expected data with data read from a selected memory cell; and
logic configured to indicate a mismatch if the compared data is not the same.

6. The memory device of claim 5, wherein logic configured to indicate a mismatch is configured to discharge a global bit line coupled to the IO mismatch detection logic.

7. The memory device of claim 6, wherein the IO mismatch detection logic further comprises:
IO match output logic configured to output a signal indicating an IO match or mismatch based on the state of the global bit line.

8. The memory device of claim 5, wherein an output of the comparison logic is coupled to the bank mismatch detection logic and wherein the bank mismatch detection logic is configured to indicate a mismatch in the associated bank if the compared data is not the same.

9. The memory device of claim 4, further comprising:
logic configured disable the IO mismatch detection logic, when not in a multi-bank test mode.

10. The memory device of claim 1, wherein the memory device is integrated into an electronic device, selected from the group consisting of a set top box, music player, video player, entertainment unit, navigation device, mobile phone, portable computer, hand-held personal communication system (PCS) units, communications device, personal digital assistant (PDA), fixed location data unit, and a computer.

11. A method for reducing memory test time, the method comprising:
simultaneously writing and reading each of a plurality of memory banks in a memory array; and
testing the plurality of memory banks simultaneously in one cycle of a clock by local matching of read data with previously written data for each bank.

12. The method of claim 11, further comprising:
enabling a multi-bank mode for testing and disabling the multi-bank mode for normal operation.

13. The method of claim 11, wherein the data written is the same for all memory banks.

14. The method of claim 11, further comprising:
precharging a global bit line coupled to the plurality of memory banks; and
discharging the global bit line upon a failure of at least one of the memory banks.

15. The method of claim 11, wherein testing further comprises:
latching the output data of a read operation;
comparing the output data to an expected data;
indicating a match if the output data and expected data are the same; and
indicating a mismatch if the output data and the expected data are different.

16. The method of claim 15, further comprising:
generating a bank mismatch signal, if a mismatch is indicated on any of a plurality of input/outputs (IO) of a bank.

17. The method of claim 16, further comprising:
generating an IO mismatch signal if any of selected IO in the plurality of memory banks indicate a mismatch.

18. The method of claim 17, wherein generating an IO mismatch signal further comprises:
discharging a global bit line coupled to the plurality of memory banks; and
latching the state of the IO mismatch signal.

19. The method of claim 16, further comprising:
generating an IO match signal if each of selected IO in the plurality of memory banks indicate a match.

20. The method of claim 11, further comprising:
holding a data signal to be written through both write and read cycles.

21. A method for reducing memory test time, the method comprising:
step for simultaneously writing and reading each of a plurality of memory banks in a memory array; and
step for testing the plurality of memory banks simultaneously in one cycle of a clock by local matching of read data with previously written data for each bank.

22. The method of claim 21, further comprising:
step for enabling a multi-bank mode for testing and disabling the multi-bank mode for normal operation.

23. The method of claim 21, wherein the data written is the same for all memory banks.

24. The method of claim 21, further comprising:
step for precharging a global bit line coupled to the plurality of memory banks; and
step for discharging the global bit line upon a failure of at least one of the memory banks.

25. The method of claim 21, wherein testing further comprises:
step for latching the output data of a read operation;
step for comparing the output data to an expected data;
step for indicating a match if the output data and expected data are the same; and
step for indicating a mismatch if the output data and the expected data are different.

26. The method of claim 25, further comprising:
step for generating a bank mismatch signal, if a mismatch is indicated on any of a plurality of input/outputs (IO) of a bank.

27. The method of claim 26, further comprising:
step for generating an IO mismatch signal if any of selected IO in the plurality of memory banks indicate a mismatch.

28. The method of claim 27, wherein generating an IO mismatch signal further comprises:
step for discharging a global bit line coupled to the plurality of memory banks; and
step for latching the state of the IO mismatch signal.

29. The method of claim 26, further comprising:
step for generating an IO match signal if each of selected IO in the plurality of memory banks indicate a match.

30. The method of claim 21, further comprising:
step for holding a data signal to be written through both write and read cycles.

31. An apparatus for reducing memory test time, the method comprising:
means for simultaneously writing and reading each of a plurality of memory banks in a memory array; and
means for testing the plurality of memory banks simultaneously in one cycle of a clock by local matching of read data with previously written data for each bank.

32. The apparatus of claim 31, further comprising:
means for enabling a multi-bank mode for testing and for disabling the multi-bank mode for normal operation.

33. The apparatus of claim 31, wherein the data written is the same for all memory banks.

34. The apparatus of claim 31, further comprising:
means for precharging a global bit line coupled to the plurality of memory banks; and
means for discharging the global bit line upon a failure of at least one of the memory banks.

35. The apparatus of claim 31, wherein the means for testing further comprises:
means for latching the output data of a read operation;
means for comparing the output data to an expected data; and
means for indicating a match if the output data and expected data are the same;
and for indicating a mismatch if the output data and the expected data are different.

36. The apparatus of claim 35, further comprising:
means for generating a bank mismatch signal, if a mismatch is indicated on any of a plurality of input/outputs (IO) of a bank.

37. The apparatus of claim 36, further comprising:
means for generating an IO mismatch signal if any of selected IO in the plurality of memory banks indicate a mismatch.

38. The apparatus of claim 37, wherein generating an IO mismatch signal further comprises:
means for discharging a global bit line coupled to the plurality of memory banks; and
means for latching the state of the IO mismatch signal.

39. The apparatus of claim 31, wherein the apparatus is integrated into an electronic device, selected from the group consisting of a set top box, music player, video player, entertainment unit, navigation device, mobile phone, portable computer, hand-held personal communication system (PCS) units, communications device, personal digital assistant (PDA), fixed location data unit, and a computer.
